(19) United States
(12) Patent Application Publication
(10) Pub. No.: US 2008/0157770 A1
(43) Pub. Date: Jul. 3, 2008

(54) DUAL-TUNED TEM/BIRDCAGE HYBRID VOLUME COIL FOR HUMAN BRAIN AND SPECTROSCOPY

(75) Inventor: Alexey S. Peshkovsky, New York, NY (US)

Correspondence Address: BOND, SCHOENECK & KING, PLLC, ONE LINCOLN CENTER, SYRACUSE, NY, 13202-1355, US

(73) Assignee: RF SENSORS, LLC, New York, NY (US)

(21) Appl. No.: 11/966,796

(22) Filed: Dec. 28, 2007

Related U.S. Application Data
(60) Provisional application No. 60/882,288, filed on Dec. 28, 2006.

(51) Int. Cl. G01R 33/34

(52) U.S. Cl. 324/318

(57) ABSTRACT

A dual-tuned hybrid resonator coil for high field multinuclear MRI/MRS combines both the TEM and the BC designs, such that the mode splitting is significantly increased. The coil includes TEM elements and BC coil windows, where the TEM elements are positioned in each of the windows and oriented orthogonally thereto. This arrangement allows retaining all of the advantages of the TEM technology at high frequencies, while drastically reducing mode mixing and the associated shading artifact.

### CROSS-REFERENCE TO RELATED APPLICATIONS

The present application claims priority to U.S. Provisional Application No. 60/882,288, filed on Dec. 28, 2006, hereby incorporated by reference.

### BACKGROUND OF THE INVENTION

1. Field of the Invention

The present invention relates to a dual-tuned hybrid resonator coil design for high field multinuclear MRI/MRS, which combines both TEM and BC technologies. More specifically, the invention relates to a dual-tuned volume coil design that retains all of the advantages of TEM technology at high frequencies, while drastically reducing mode mixing and the associated shading artifact.

2. Description of the Related Art

Multinuclear magnetic resonance imaging (MRI) and magnetic resonance spectroscopy (MRS) are greatly benefited by the use of dual-tuned radiofrequency (RF) coils capable of resonating simultaneously at two frequencies, where the higher one corresponds to the 1H nucleus and the lower one to an X nucleus, such as ³¹P or ¹³C. These coils help save imaging time and avoid repositioning artifacts arising, for example, from interchanging the ¹H imaging coil and ³¹P spectroscopic coil during the ³¹P and ¹³C spectroscopic imaging of the human brain. Spatial co-registration of data from all involved frequencies also becomes possible when dual-tuned coils are used. Further, proton decoupling during spectroscopic acquisition may be performed with these devices, resulting in dramatic signal-to-noise ratio (SNR) improvements. An ideal dual-tuned volume coil should function simultaneously at two frequencies without a need for retuning or reconnecting, be capable of quadrature operation (to further improve SNR and reduce specific absorption rates (SAR)), provide uniform RF fields, and maintain high efficiency and sensitivity. It is also desirable that such coil, while providing the advantages of dual-frequency operation, not introduce new unwanted artifacts due to interactions between the coil parts corresponding to the two different frequencies.

Many dual-tuned birdcage coil (BC) designs have been developed. See Rath A R. Design and Performance of a Double-Tuned Bird-Cage Coil. J Mag Reson 1990; 86:488-495; Fitzsimmons J R, Beck B L, Brooker H R. Double Resonant Quadrature Birdcage. Magn Reson Med 1993; 30:107-114; Murphy-Boesch J, Srinivasan R, Carvajal L, Brown T R. Two Configurations of the Four-Ring Birdcage Coil for 1H Imaging and 1H-Decoupled 31P Spectroscopy of the Human Head. J Mag Reson 1994; B 103:103-114; Shen G X, Wu J F, Boada F E, Thulborn K R. Experimentally Verified, Theoretical Design of Dual-Tuned, Low-Pass Birdcage Radiofrequency Resonators for Magnetic Resonance Imaging and Magnetic Resonance Spectroscopy of Human Brain at 3.0 Tesla. Magn Reson Med 1999; 41:268-275; and Matson G B, Vermathen P, Hill T C. A Practical Double-Tuned 1H/31P Quadrature Birdcage Headcoil Optimized for 31P Operation. Magn Reson Med 1999; 42:173-182, all of which are hereby incorporated by reference. These devices are known to provide very uniform RF fields and can easily be driven in quadrature. However, at field strengths above 4 T (and, therefore, at the associated high RF frequencies above 170 MHz), BC coils, in general, are outperformed by transverse electromagnetic (TEM) coils, see U.S. Pat. No. 4,751,464, hereby incorporated by reference, which have been reported for the field strengths up to 7 T for body, see Vaughan T, Snyder C, DelaBarre L, Bolinger L, Tian J, Andersen P, Strupp J, Adriany G, Ugurbil K. 7T Body Imaging First Results. Proc Intl Soc Mag Reson Med 2006; 14:21, hereby incorporated by reference, and 9.4 T for head MRI, see Vaughan J, DelaBarre L, Snyder C, Tian J, Andersen P, Strupp J, Adriany G, Van de Moortele P-F, Ugurbil K. 9.4T Human Imaging: Preliminary Results. Proc Intl Soc Mag Reson Med 2006; 14:529, hereby incorporated by reference. Because the inductances of the “windows” comprising BC coils increase with the coils' overall sizes, unreasonably low value capacitors may be required to resonate large BC coils at high frequencies. Size scaling of TEM coils, on the other hand, is much easier, since the area of the elements comprising a TEM coil can be controlled by adjusting the distance between the coil's legs and its shield. Additional advantages of the TEM coils include absence of end ring currents and better sensitivity. See Vaughan J T, Hetherington H P, Otu J O, Pan J W, Pohast G M. High Frequency Volume Coils for Clinical NMR Imaging and Spectroscopy. Magn Reson Med 1994; 32:206-218, and Vaughan J T, Garwood M, Collins C M, Liu W, DelaBarre L, Adriany G, Andersen P, Merkle H, Goebel R, Smith M B, Ugurbil K. 7T vs. 4T: RF Power, Homogeneity, and Signal-to-Noise Comparison in Head Images, Magn Reson Med 2001; 46:24-30, hereby incorporated by reference. Running experiments at high fields is known to yield superior SNR, which is often a limiting factor at X nuclei (13C and 31P) frequencies. Consequentially, dual-tuned TEM coils are currently in high demand for high-field multinuclear MRI/MRS.

Prior art dual-tuned TEM coils are commonly constructed by placing elements needed for the high frequency (¹H) operation in between those for the lower frequency X nuclei in an alternating fashion. This arrangement, however, causes substantial decrease (from about 10-15 MHz to about 2-3 MHz at 4 T) in the mode splitting at the higher ¹H frequency, as a result of significant residual coupling between the ¹H and X nuclei elements. The reduction in mode splitting makes the dual-tuned TEM coils susceptible to mode mixing induced by disrupted symmetry, such as uneven accumulation of coil component tolerances or asymmetrical positioning of the imaged objects. Mode mixing, in turn, results in shading artifact, which may severely degrade image quality. See Tropp J. A Model for Image Shading in Multi-mode Resonators. Proc Intl Soc Mag Reson Med 2001; 9:1129, hereby incorporated by reference. Therefore, despite their efficiency, such dual-tuned TEM devices are not optimal for the high-field multinuclear MRI/MRS.

### BRIEF SUMMARY OF THE INVENTION

The present invention provides a dual-tuned hybrid resonator coil for high-field multinuclear MRI/MRS that combines both TEM and BC designs. The device is preferably made such that its TEM part operates at the higher ¹H frequency. The BC part of the device is constructed in a high-pass or low-pass configuration and operates at a lower X nucleus (for example, ¹³C or ³¹P) frequency. This arrangement allows retaining all of the advantages of TEM technology at high frequencies, while permitting a significant increase in the mode splitting (as compared with prior art dual-tuned TEM devices) and, consequentially, drastically reducing mode mixing and the associated shading artifact. Mode splitting is increased due to the geometrical orthogonality between the TEM elements and the BC windows, which reduces coupling between the hybrid coil parts operating at the ¹H and the X nucleus frequencies. Other arrangements and configurations of TEM and BC parts in this invention are also possible.

### BRIEF DESCRIPTION OF THE DRAWINGS

The present invention will be more fully understood and appreciated by reading the following Detailed Description in conjunction with the accompanying drawings, in which:

FIG. 1 is a schematic of a prior art dual-tuned TEM coil design as a combination of two single-tuned TEM coils resonating at two different frequencies, showing half-open structures for clarity.

FIG. 2 is a schematic of a general layout of a dual-tuned TEM/BC hybrid resonator coil according to the present invention that incorporates elements of both TEM and BC designs, showing half open structures for clarity.

FIG. 3A is a schematic of an arrangement of conductors and capacitors in prior art low-pass BC coil, with only two windows of the coil shown to better illustrate the interconnection pattern.

FIG. 3B is a schematic of an essentially equivalent arrangement to FIG. 3A with two capacitors at the ends of each rung replacing one capacitor in the middle of each rung, with only two windows of the coil shown to better illustrate the interconnection pattern.

FIG. 4A is a schematic of an arrangement of conductors and capacitors in common high pass BC coil used in the prior art, with only two windows of the coil shown to better illustrate the interconnection pattern.

FIG. 4B is a schematic of an essentially equivalent arrangement to FIG. 4A with capacitors placed on the side rather than in the middle of the sections of the end-rings in each coil window, with only two windows of the coil shown to better illustrate the interconnection pattern.

FIG. 5A is a schematic of prior art TEM coil designs made of conductors and lumped element capacitors.

FIG. 5B is a schematic of prior art TEM coil designs with coaxial transmission line segments connected to a shield.

FIG. 6A is a schematic of the preferred embodiments of the low-pass BC coil designs used in connected with the present invention, and FIG. 6B is a schematic of the high-pass BC coil designs used in connection with the present invention, where the rungs and the capacitors shown in FIGS. 3B and 4B have been replaced with coaxial transmission line segments.

FIG. 7 is a schematic of two preferred embodiments of the disclosed invention that simultaneously incorporate the transmission line-based TEM design and the low-pass (part A) or the high-pass (part B) transmission line-based BC design (as in FIG. 6).

FIG. 8 is a schematic of capacitive (A), inductive for BC (B) and inductive for TEM (C) coil driving and matching connections used in the prior art.

FIG. 9 is a schematic of a two-port quadrature coil driving network used in the prior art for dual-tuned TEM or dual-tuned BC, with the driving and matching connections comprising those shown in FIG. 8.

FIG. 10 is a schematic of a four-port quadrature coil driving network of the present invention, with the driving and matching connections comprising those seen in FIG. 8.

FIG. 11 is a schematic of the 0°-180° phased splitter of the present invention.

FIG. 12 is photograph of a preferred embodiment according to the present invention including transmission line segments.

FIG. 13 is a graph of the resonance modes of the ¹H part (A) and the ³¹P part (C) of the present invention, with the ¹H part (B) and the ³¹P part (D) of a prior art dual-tuned ¹H/³¹P TEM coil also shown.

### DETAILED DESCRIPTION OF THE INVENTION

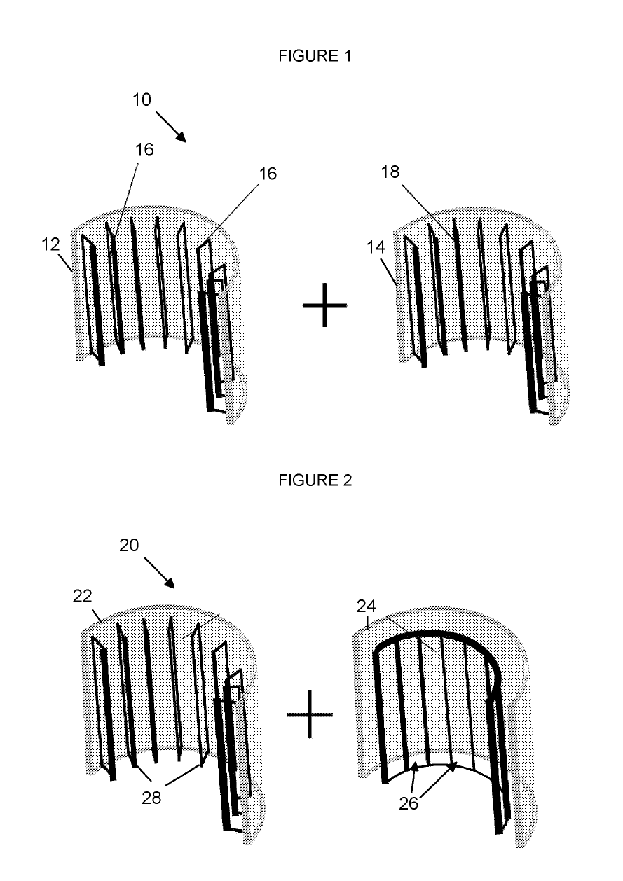

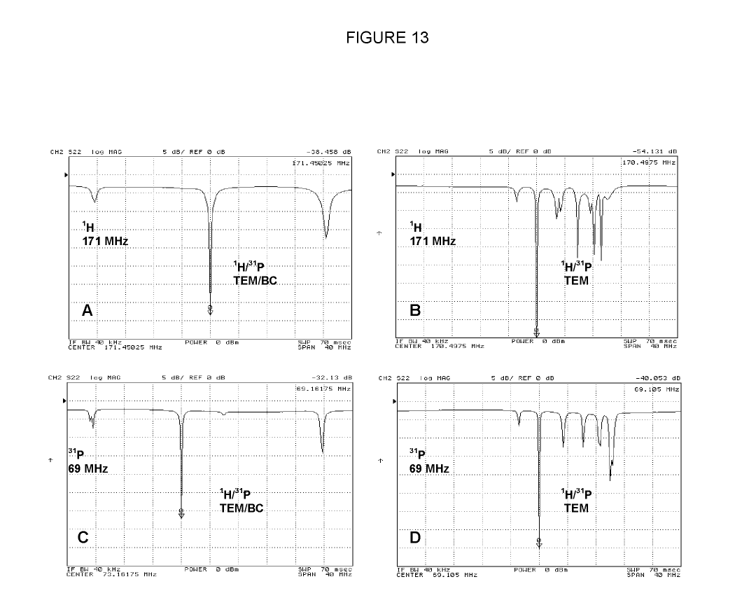

Referring now to the drawings, wherein like reference numerals refer to like parts throughout, the present invention comprises a number of preferred embodiments of combinations of TEM and BC technologies into a hybrid coil. As described above, it is desirable to utilize TEM technology when high frequencies are involved. Prior art dual-tuned TEM devices 10 are constructed by essentially combining two single-tuned TEM coils 12 and 14 resonating at two different frequencies, respectively, as seen in FIG. 1, such that the TEM coil elements 16 corresponding to the ¹H frequency part are positioned in between the TEM coil elements 18 corresponding to the X nucleus frequency part. Although tuned to different frequencies, the resulting neighboring elements 16 and 18 posses substantial residual coupling, being positioned essentially in the same plane and in close proximity to each other. This residual coupling leads to drastic reduction in the frequency separation between the resonance modes (mode splitting) of coils 12 and 14 in the ¹H coil part (see FIGS. 13B and 13D), in turn resulting in mode mixing and shading artifact, which may severely degrade the image quality.

Referring to FIG. 2, a hybrid, dual-tuned TEM/BC coil 20 according to the present invention combines TEM and BC arrangements 22 and 24, such that the advantages of using TEM technology at the high ¹H frequencies are retained, while coupling between the elements corresponding to the parts operating at the two frequencies is practically eliminated, thereby restoring mode splitting to the values observed for single-tuned coils (see FIGS. 13A and 13C) and drastically reducing shading artifact. Coupling is minimized because the windows 26 of the BC part of the present invention are geometrically orthogonal to the elements 28 of the TEM portion of the coil.

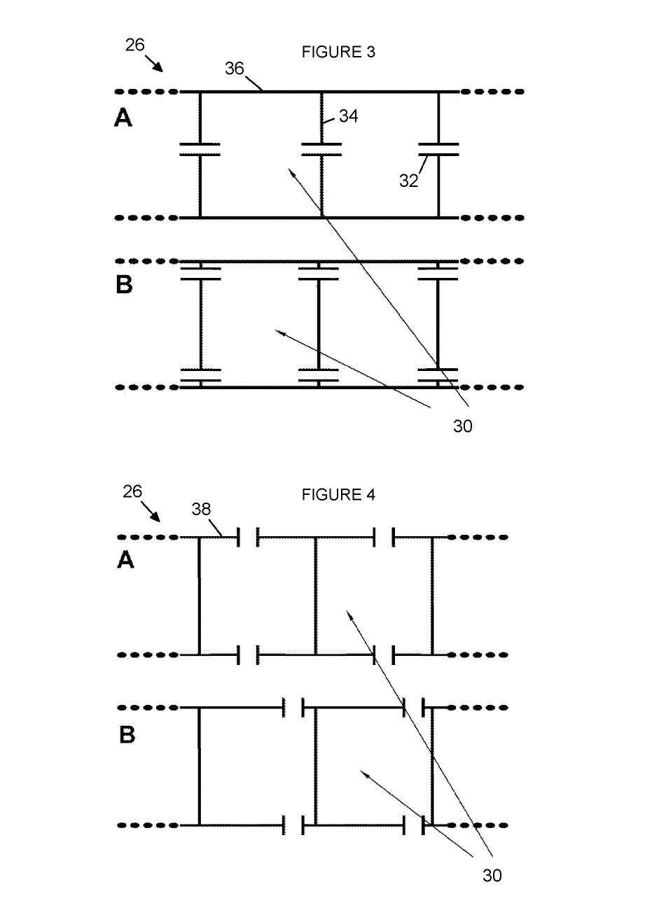

Multiple designs of TEM and BC coils exist in the prior art and may be used in connection with the present invention, giving rise to several preferred embodiments of coil 20. Lumped element BC coils 26 in the prior art generally comprise windows 30 using lumped element capacitors 32 and conductors 34. Windows 30 can have low-pass 36 (see FIG. 3), high-pass 38 (see FIG. 4), or hybrid (not shown) configurations.

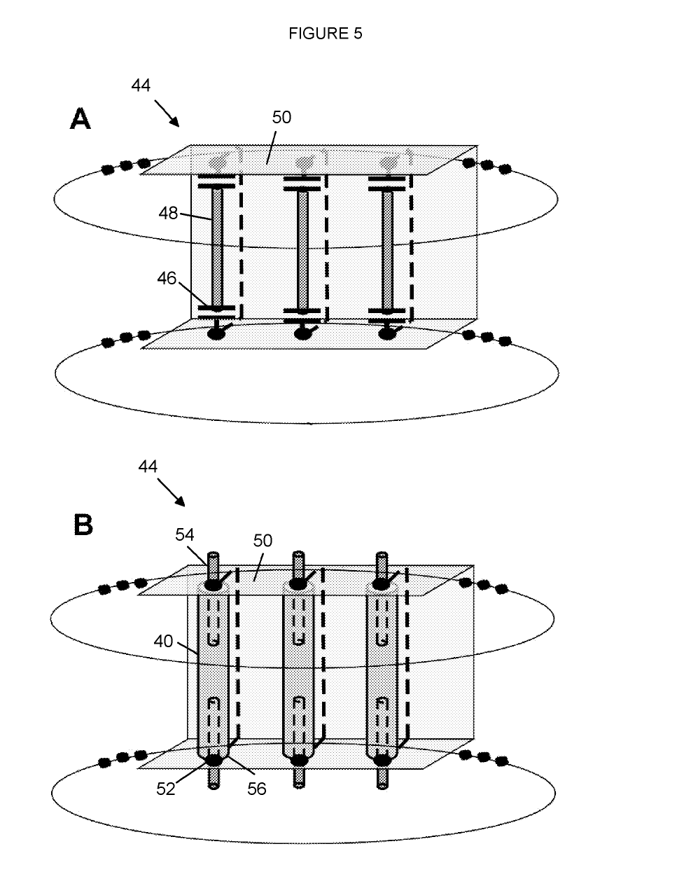

Referring to FIGS. 5A and 5B, TEM coils 44 generally comprise lumped element capacitors 46, conductors 48 and a shield 50, as seen in FIG. 5A, or transmission line segments 40 and a shield 50, as seen in FIG. 5B. Segments 40 generally include inner and outer conductors, 54 and 56, respectively, where inner conductor 54 is moveable with respect to the outer conductor 56, and each segment 40 is interconnected to shield 50 via a contact point 52 between inner conductor 54 and shield 50. Transmission line segments 40 may thus be constructed in the manner known to those of skill in the art, such as that disclosed in U.S. Pat. No. 4,746,866, hereby incorporated by reference. Although a cylindrical design is implied in FIGS. 5A and 5B, open designs are also possible. Other designs for TEM devices either known in the prior art or newly developed may be utilized as components of the disclosed invention.

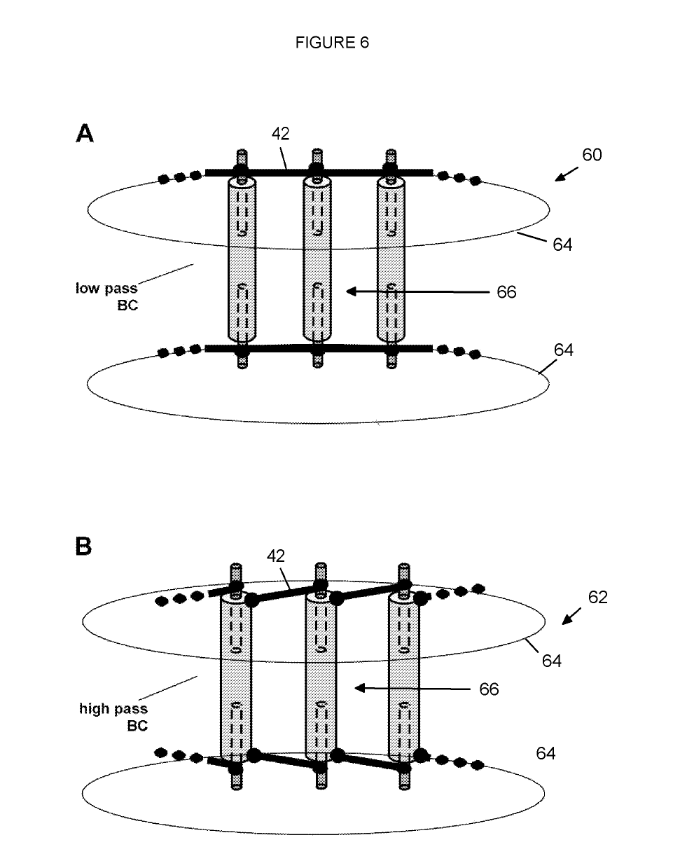

Referring to FIGS. 6A and 6B, the present invention also encompasses new designs for BC coils comprising coaxial transmission line segments 40, constructed as described above, and conductors 42 that are arranged into low-pass 60 (see FIG. 6A), high-pass 62 (see FIG. 6B), or hybrid (not shown) configurations. Segments 40 as described above are interconnected to a common conductor 64, such as an end ring, to form a BC window 66. Although a cylindrical design is implied in FIGS. 6A and 6B, open designs are also possible. Other designs for BC devices either known in the prior art or newly developed may be utilized as components of the disclosed invention.

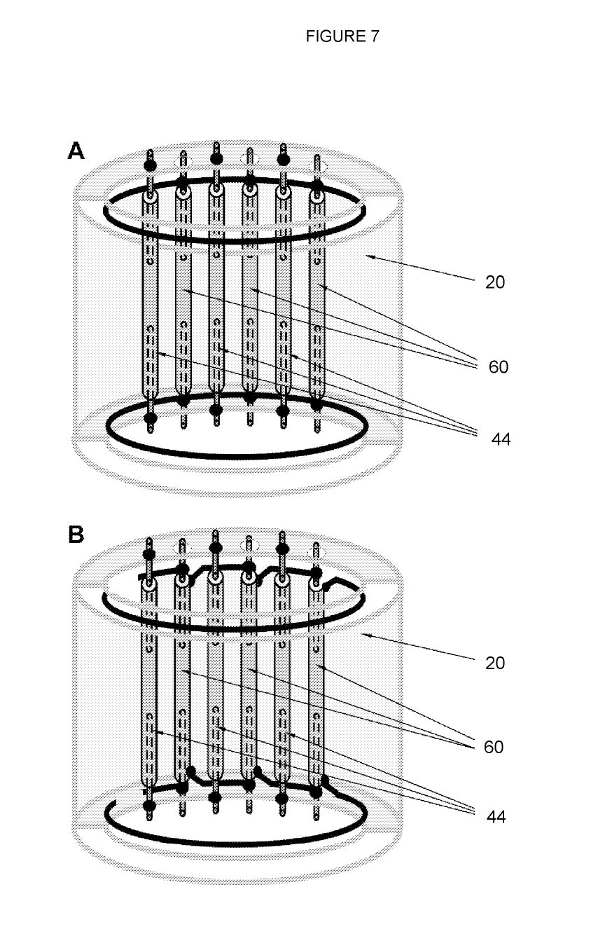

In a first preferred embodiment, coil 20 comprises a combination of transmission line-based TEM coil 44, as seen in FIG. 5B, and transmission line-based low-pass BC coil 60, as seen in FIG. 6A, that are combined and constructed as shown in FIG. 7A. Similar transmission line segments 40 are used for both the TEM and the BC parts, such that the segments 40 used for the TEM portion of the invention are placed in the middle of the windows 66 of the BC portion of the invention and are positioned orthogonal thereto to remove residual coupling between the coil parts working at the ¹H and the X nucleus frequencies. The TEM portion 44 of coil 20 is preferably used for the high ¹H frequency operation and BC portion 60 of coil 20 for the lower X nucleus frequency operation, although in other preferred embodiments this arrangement may be reversed.

In a second preferred embodiment, coil 20 is a combination of transmission line-based TEM coil 44, as seen in FIG. 5B, and transmission line-based high-pass BC coil 62, as seen in FIG. 6B, and constructed as shown in FIG. 7B. Similar transmission line segments 40 are used for both the TEM and the BC parts, such that the TEM elements 28 are placed in the middle of the BC windows 66 and positioned orthogonally thereto to remove residual coupling between the coil parts working at the ¹H and the X nucleus frequencies. TEM part 44 of coil 20 is preferably used for the high ¹H frequency operation and BC part 62 for the lower X nucleus frequency operation, although in other preferred embodiments this arrangement may be reversed.

In a third preferred embodiment, coil 20 is a combination of lumped element capacitor-based TEM coil 44, as seen in FIG. 5A, and transmission line-based low-pass BC coil 60, as seen in FIG. 6A, constructed similarly to the first and the second preferred embodiments. TEM elements 28 are placed in the middle of the BC windows 66 and positioned orthogonally thereto to remove residual coupling between the portions of the invention working at the ¹H and the X nucleus frequencies. The TEM part 44 of coil 20 is preferably used for the high ¹H frequency operation and BC part 60 for the lower X nucleus frequency operation, although in other preferred embodiments this arrangement may be reversed.

In a fourth preferred embodiment, the dual-tuned TEM/BC hybrid resonator coil is a combination of lumped element capacitor-based TEM coil 44, as seen in FIG. 5A, and transmission line-based high-pass BC coil 62, as seen in FIG. 6B, constructed similarly to the first and the second preferred embodiments. TEM elements 28 are placed in the middle of the BC windows 66 and positioned orthogonally thereto to remove residual coupling between the coil parts working at the ¹H and the X nucleus frequencies. TEM portion 44 of coil 20 is preferably used for the high ¹H frequency operation and BC portion 62 of coil 20 for the lower X nucleus frequency operation, although in other preferred embodiments this arrangement may be reversed.

In a fifth preferred embodiment, coil 20 comprises a combination of transmission line-based TEM coil 44, as seen in FIG. 5B, and lumped element capacitor-based low-pass BC coil 26, as seen in FIG. 3A, constructed similarly to the first and the second preferred embodiments. TEM elements 28 are placed in the middle of the BC windows 30 and are positioned orthogonally thereto to remove residual coupling between the coil parts working at the ¹H and the X nucleus frequencies. TEM portion 44 of coil 20 is preferably used for the high ¹H frequency operation and BC portion 26 of coil 20 for the lower X nucleus frequency operation, although in other preferred embodiments this arrangement may be reversed.

In a sixth preferred embodiment, the dual-tuned TEM/BC hybrid resonator coil is a combination of transmission line-based TEM coil 44, as seen in FIG. 5B, and lumped element capacitor-based high-pass BC coil 26, as seen in FIG. 4, constructed similarly to the first and the second preferred embodiments. TEM elements 28 are placed in the middle of the BC windows 30 and are positioned orthogonally thereto to remove residual coupling between the coil parts working at the ¹H and the X nucleus frequencies. TEM portion 44 of coil 20 is preferably used for the high ¹H frequency operation and BC portion 26 of coil 20 for the lower X nucleus frequency operation, although in other preferred embodiments this arrangement may be reversed.

In a seventh preferred embodiment, coil 20 is a combination of lumped element capacitor-based TEM coil 44, as seen in FIG. 5A, and lumped element capacitor-based low-pass BC coil 26, as seen in FIG. 3, that is constructed similarly to the first and the second preferred embodiments. TEM elements 28 are placed in the middle of the BC windows 30 and are positioned orthogonally thereto to remove residual coupling between the coil parts working at the ¹H and the X nucleus frequencies. TEM portion 44 of coil 20 is preferably used for the high ¹H frequency operation and BC portion 26 of coil 20 for the lower X nucleus frequency operation, although in other preferred embodiments this arrangement may be reversed.

In an eighth preferred embodiment, coil 20 is a combination of lumped element capacitor-based TEM coil 44, as seen in FIG. 5A, and lumped element capacitor-based high-pass BC coil 26, as seen in FIG. 4, that is constructed similarly to the first and the second preferred embodiments. TEM elements 28 are placed in the middle of the BC windows 30 and are positioned orthogonally thereto to remove residual coupling between the coil parts working at the ¹H and the X nucleus frequencies. TEM portion 44 of coil 20 is preferably used for the high ¹H frequency operation and BC portion 26 of coil 20 for the lower X nucleus frequency operation, although in other preferred embodiments this arrangement may be reversed.

In a ninth preferred embodiment, coil 20 is a combination of transmission line-based low-pass BC coil 60, as seen in FIG. 6A, and transmission line-based high-pass BC coil 62, as seen in FIG. 6B. The low-pass BC coil rungs, i.e., corresponding transmission line segments 40, are positioned in between the high-pass BC coil rungs, i.e., corresponding transmission line segments 40, such that the windows 66 corresponding to each of the two dual-tuned coil parts 60 and 62 are half-way overlapped. High-pass BC portion 62 of coil 20 is preferably used for the high ¹H frequency operation and the low-pass BC portion 60 of coil 20 for the lower X nucleus frequency operation, although in other preferred embodiments this arrangement may be reversed.

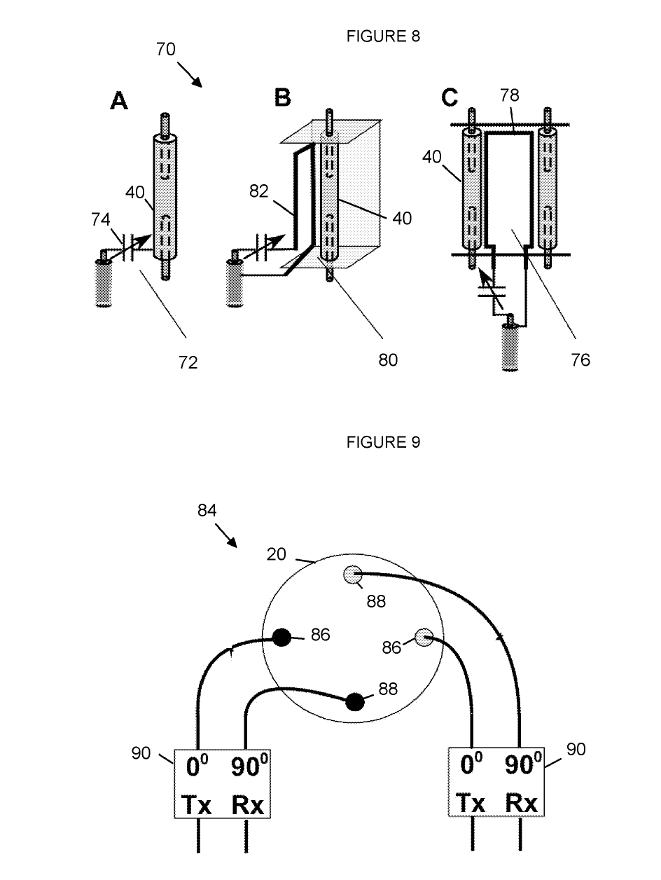

Referring to FIGS. 8-11, the present invention encompasses several embodiments of driving networks 70 used for of driving both parts of coil 20. For example, conventional capacitive driving networks 72 having adjustable capacitors 74 (as seen in FIG. 8A), inductive driving networks 80 for TEM arrangements 22 having inductive loops 82 (as seen in FIG. 8B), and inductive driving networks 76 for BC arrangements 24 having inductive loops 78 (FIG. 8C), along with related coil driving and matching connections may be utilized interchangeably and in any combination in conjunction with two-port or four-port driving networks according to the present invention, as further described herein.

Referring to FIG. 9, a conventional two-port quadrature coil driving network 84 for conventional dual-tuned TEM or dual-tuned BC arrangements may be used to drive the preferred embodiments of coil 20 according to the present invention. The driving and matching connections utilized in conjunction with network 84 are seen in FIG. 8. In such configurations, each part of coil 20 receives a pair of connections 86 and 88 to a quadrature hybrid splitter 90 that are placed geometrically at 90° with respect to each other to permit independent quadrature operation at each frequency.

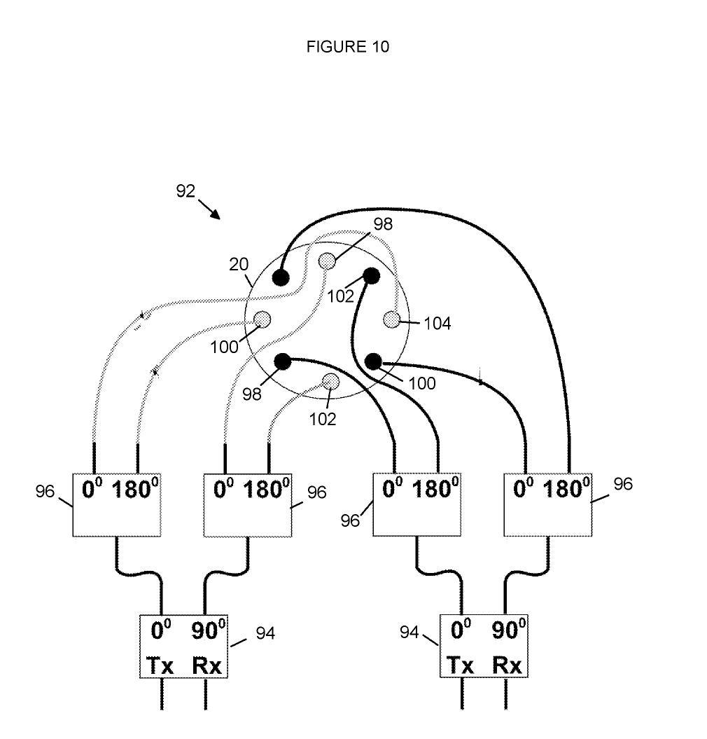

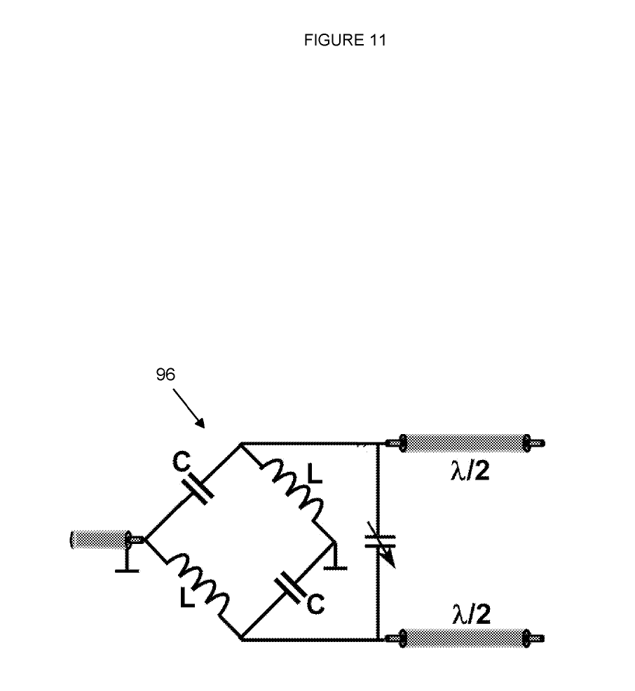

Referring to FIGS. 10 and 11, the present invention encompasses a four-port quadrature driving network 92. Network 92 is applied individually to each part of coil 20 using a 90° hybrid quadrature splitter 94 followed a pair of 0°-180° phased power splitters 96. The driving and matching connections that may be utilized in conjunction with this arrangement are seen in FIG. 8. Each part of coil 20 receives four connections 98, 100, 102, and 104, placed geometrically at 90° to each other to permit independent quadrature operation at each frequency. Referring to FIG. 11, 0°-180° phased power splitter 96 according to the present invention comprises a series of capacitors, C, and inductors, L, where the values are chosen such that the relationship ωL=1/ωC=50Ω, where ω is the resonance frequency of the corresponding part of the coil.

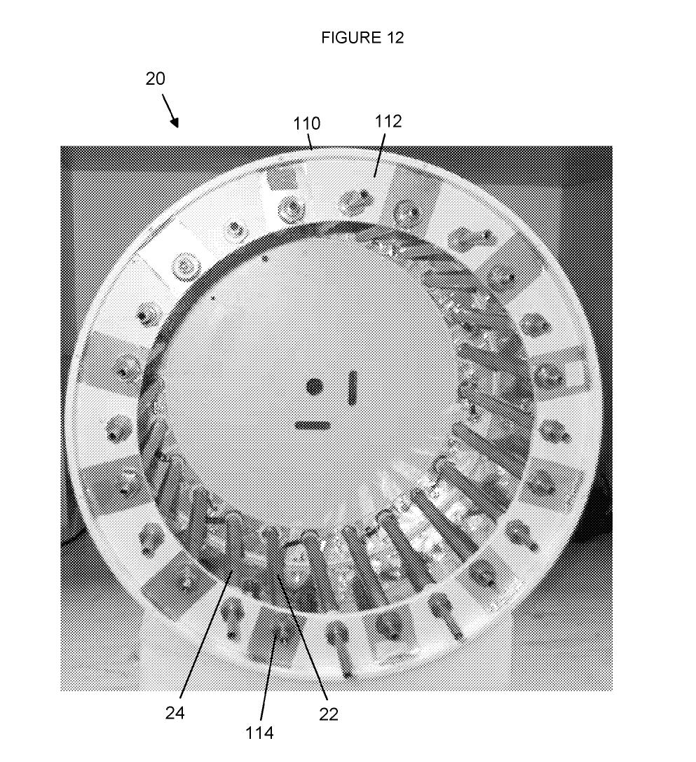

The experimental performance evaluation of coil 20 according to the present invention was carried out using the second preferred embodiment of coil 20, which comprised a 24-element (12 for each frequency) ¹H/³¹P head coil, built using tunable capacitive coaxial transmission line segments 40 for both TEM and BC portions, as seen in FIG. 12. Coil 20 included a shield 110 and an end cap 112. TEM portion of coil 22 was constructed of adjustable coaxial transmission line segments 40 connected to shield 110 by a sliding contact 114. Segments 40 comprising the BC portion of coil 24 were located between segments 40 used to form the TEM portion of coil 22, and were attached to the same plastic former, but were electrically isolated from shield 110. To decrease the resonance frequency of the ³¹P BC part of coil 20, 100 pF capacitors were soldered across each of the BC coaxial transmission line segments 40. The RF cavity (shield) id was 34.5 cm; the coil length was 20 cm with all 24 elements positioned at a diameter of 28.5 cm. Both portions of coil 20 (TEM and BC) were driven in quadrature using two-port drives (as seen in FIG. 9) and capacitive matching (as seen in FIG. 8A). Isolation between the quadrature channels of each part of coil 20, as well as between the ¹H and ³¹P parts themselves, was better than −20 dB.

FIGS. 13A and 13C show the resonance modes of coil 20 in comparison to those of a similar sized, prior art dual-tuned ¹H/³¹P TEM coil. The separation between the modes of the ¹H part of coil 20 was 17 MHz (see FIG. 13A), while for the ¹H/³¹P TEM it was only about 2.5-3 MHz (see FIG. 13B). Since the windows of the BC and the inductive elements of the TEM in the coil 20 are positioned at 90° relative to each other, the coupling between them is practically eliminated, thereby restoring the mode separation in the ¹H TEM part of coil 20. The mode separation for the ³¹P part was also improved (compare FIG. 13C to FIG. 13D) due to the intrinsically strong coupling between the resonance meshes of the BC portion of coil 20 compared with that between the elements of the TEM portion of coil 20. Using transmission line segments 40 with variable capacitances for both the TEM and the BC parts provided an easy way of tuning and adjusting the RF currents in the elements of both coil parts to mimic sinusoidal distribution. Efficiency of coil 20 and a comparable dual-tuned TEM coil was the same at both frequencies (measured as power required to produce a 90° pulse), within 1 dB experimental error, despite of coil 20 being about 15-20% larger, which would normally decrease efficiency.

What is claimed is:

1. A hybrid resonator coil, comprising:
a plurality of TEM elements; and
a plurality of birdcage coil windows, wherein each of said plurality of elements are positioned in each of said windows and oriented orthogonally thereto.

2. The coil of claim 1, wherein said elements comprise transmission line segments including an outer conductor and an inner conductor positioned in said out conductor and moveable relative thereto.

3. The coil of claim 2, wherein said windows are formed from transmission line segments including an outer conductor and an inner conductor positioned in said out conductor and moveable relative thereto.

4. The coil of claim 3, wherein said transmission line segments are arranged in a low pass configuration.

5. The coil of claim 3, wherein said transmission line segments are arranged in a high pass configuration.

6. The coil of claim 2, wherein said windows are formed from lumped element capacitors.

7. The coil of claim 6, wherein said lumped element capacitors are arranged in a low pass configuration.

8. The coil of claim 6, wherein said lumped element capacitors are in a high pass configuration.

9. The coil of claim 1, wherein said elements comprise lumped element capacitor elements.

10. The coil of claim 9, wherein said windows are formed from transmission line segments.

11. The coil of claim 10, wherein said transmission line segments are arranged in a low pass configuration.

12. The coil of claim 10, wherein said transmission line segments are arranged in a high pass configuration.

13. The coil of claim 9, wherein said windows are formed from lumped element capacitors.

14. The coil of claim 13, wherein said lumped element capacitors are arranged in a low pass configuration.

15. The coil of claim 13, wherein said lumped element capacitors are in a high pass configuration.

16. A hybrid resonator coil, comprising:
a plurality of TEM elements;
a plurality of birdcage coil windows, wherein each of said plurality of elements are positioned in each of said windows and oriented orthogonally thereto; and
a driving network interconnected to said elements and said windows.

17. The coil of claim 16, wherein said driving network comprises a four port quadrature driving network.

18. The coil of claim 17, wherein said four port quadrature driving network comprises two ninety degree splitter and two phased one hundred eighty degree splitters interconnected to each of said ninety degree splitters.

19. The coil of claim 18, wherein said four port quadrature driving network further comprises four connections interconnecting said network to four of said plurality of elements and four connections interconnecting said network to said windows.

20. The coil of claim 19, wherein said four port quadrature driving network is configured according to the relationship of ω=1/ωC=50Ω, wherein ω is the resonance frequency of the corresponding said plurality of TEM elements and said plurality of birdcage windows.
